(19) United States
(12) Patent Application Publication
(10) Pub. No.: US 2018/0046046 A1
(43) Pub. Date: Feb. 15, 2018

(54) ARRAY SUBSTRATE, METHOD FOR MANUFACTURING THE SAME, AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Bo FENG, Beijing (CN); Qing MIAO, Beijing (CN); Yu MA, Beijing (CN)

(73) Assignees: BOE TECHNOLOGY GROUP CO., LTD., Beijing (CN); BEIJING BOE DISPLAY TECHNOLOGY CO., LTD., Beijing (CN)

(21) Appl. No.: 15/511,702

(22) PCT Filed: Mar. 30, 2016
(86) PCT No.: PCT/CN2016/077858

§ 371 Date: Mar. 16, 2017

(30) Foreign Application Priority Data
May 4, 2015 (CN) 201510221498.9

(51) Int. Cl. G02F 1/1362; H01L 21/768; G02F 1/1343; H01L 29/417; G02F 1/1368; H01L 27/12

(52) U.S. Cl. CPC G02F 1/136227; G02F 1/1368; H01L 27/1288; G02F 1/13439; H01L 29/41733; H01L 21/76804

(57) ABSTRACT

An array substrate includes a plurality of pixel regions, each of which includes: a pixel electrode and a drain electrode arranged on a same layer and independent from each other. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. A first via hole and a second via hole penetrating through the insulation layer are formed in the insulation layer at a position corresponding to the drain electrode and at a position corresponding to the pixel electrode, respectively. The drain electrode is connected to the conductive part through the first via hole, and the pixel electrode is connected to the conductive part through the second via hole.

### CROSS REFERENCE OF RELATED APPLICATION

The present application claims a priority of Chinese Patent Application No. 201510221498.9 filed on May 4, 2015, the disclosure of which is incorporated herein by reference in its entirety.

### TECHNICAL FIELD

The present disclosure relates to the technical field of displaying, and in particular to an array substrate, a method for manufacturing the array substrate and a display device.

### BACKGROUND

A liquid crystal display (LCD) has advantages such as small size, light weight, low power consumption, low radiation and low manufacturing cost, and thus has been widely used in various electric devices such as a monitor, a television, a mobile phone, a digital camera and other digital electric devices. A Thin Film Transistor Liquid Crystal Display (TFT-LCD) is a main type of flat panel display (FPD).

Based on a direction of an electric field for driving liquid crystal molecules, the TFT-LCDs are divided into three types: i.e. a vertical electric field type of TFT-LCD, a horizontal electric field type of TFT-LCD and a multidimensional electric field type of TFT-LCD. In the vertical electric field type of TFT-LCD, pixel electrodes are formed on an array substrate, and common electrodes are formed on a color filter substrate; and in a horizontal electric field type of TFT-LCD and a multidimensional electric field type of TFT-LCD, both the pixel electrodes and the common electrodes are both formed on the array substrate. The vertical electric field type of TFT-LCD includes a Twist Nematic (TN) type of TFT-LCD. The horizontal electric field type of TFT-LCD includes an In-Plane Switching (IPS) type of TFT-LCD. The multidimensional electric field type of TFT-LCD includes ADvanced Super Dimension Switch (ADS) type of TFT-LCD. For example, in the ADS type of TFT-LCD, a multidimensional electric field is formed by an electric field generated at edges of silt electrodes in a same plane and another electric field generated between a slit electrode layer and a plate-like electrode layer, so as to rotate all of orientation liquid crystal molecules right above the slit electrodes and between the slit electrodes in a liquid crystal cell, and thus improving liquid crystal operation efficiency and light transmission efficiency. The ADS technique may improve a display quality of the TFT-LCD, and has advantages such as high resolution, high transmittance, low power consumption, wide viewing angle, high aperture ratio, low chromatic aberration and push mura free.

In a conventional High transmittance ADS (HADS) array substrate, the positions of the common electrodes and the positions of the pixel electrodes are exchanged as compared with an ADS array substrate. In the conventional HADS array substrate, the pixel electrode directly overlaps a drain electrode of the transistor. As a result, a defect of dislocation may easily occur at a position of an overlapping slope, which may adversely affect a normal operation of the array substrate and reduce a yield rate of the array substrate.

### SUMMARY

An object of the present disclosure is to provide an array substrate, a method for manufacturing the array substrate and a display device, so as to improve a connection between the pixel electrode and the drain electrode, and improve the yield rate of the array substrate.

In the present disclosure, it is provided the following technical solutions for solving the above technical problem.

In one aspect, the present disclosure provides in some embodiments an array substrate including a plurality of pixel regions, wherein each of the pixel regions includes: a pixel electrode and a drain electrode arranged on a same layer and independent from each other. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole.

Optionally, the insulation layer is a passivation layer or a gate insulation layer.

Optionally, in the case that the insulation layer is the passivation layer, the conductive part and a common electrode are arranged on a same layer and made of a same material.

Optionally, in the case that the insulation layer is the gate insulation layer, the conductive part and a gate electrode are arranged on a same layer and made of a same material.

Optionally, a step-like structure is arranged in the first via hole and/or the second via hole.

Optionally, the conductive part is a conductive connection line or a conductive connection strip.

In another aspect, the present disclosure provides a display device including the above array substrate.

In yet another aspect, the present disclosure provides a method for manufacturing an array substrate including a plurality of pixel regions. The method includes: forming a pixel electrode, a drain electrode and a conductive part in each of the pixel regions. The pixel electrode and the drain electrode are arranged on a same layer and independent from each other, and the pixel electrode and the drain electrode are connected by the conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole.

Optionally, the insulation layer is a passivation layer, and forming the pixel electrode, the drain electrode and the conductive part includes: forming the pixel electrode and the drain electrode that are arranged on the same layer and independent from each other; forming the passivation layer covering the pixel electrode and the drain electrode, forming a first via hole in the passivation layer at a position corresponding to the drain electrode, and forming a second via hole in the passivation layer at a position corresponding to the pixel electrode, wherein each of the first via hole and the second via hole penetrates through the passivation layer; and forming a common electrode and the conductive part on the passivation layer through a single patterning process, wherein the drain electrode is connected to the conductive part through the first via hole, and the pixel electrode is connected to the conductive part through the second via hole.

Optionally, the forming the passivation layer includes: forming a layer of a passivation layer material; coating the layer of the passivation layer material with photoresist, exposing and developing the photoresist by a half-tone mask plate or a grey-tone mask plate, to form a photoresist reserved region, a photoresist partially-reserved region and a photoresist unreserved region; etching the passivation layer material in the photoresist unreserved region to form a first portion of the first via hole and a first portion of the second via hole; ashing the photoresist in the photoresist partially-reserved region, and etching the passivation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and removing the photoresist in the photoresist reserved region.

Optionally, the insulation layer is a gate insulation layer, and forming the pixel electrode, the drain electrode and the conductive part includes: forming a gate electrode and a conductive part through a single patterning process; forming the gate insulation layer covering the gate electrode and the conductive part, forming a first via hole in the gate insulation layer at a position corresponding to the drain electrode, and forming a second via hole in the gate insulation layer at a position corresponding to the pixel electrode, wherein each of the first via hole and the second via hole penetrates through the gate insulation layer; and forming the pixel electrode and the drain electrode on the gate insulation layer, wherein the pixel electrode and the drain electrode are independent from each other, the drain electrode is connected to the conductive part through the first via hole, and the pixel electrode is connected to the conductive part through the second via hole.

Optionally, forming the gate insulation layer includes: forming a layer of a gate insulation layer material; coating the layer of the gate insulation layer material with photoresist, exposing and developing the photoresist by a half-tone mask plate or a grey-tone mask plate, to form a photoresist reserved region, a photoresist partially-reserved region and a photoresist unreserved region; etching the gate insulation layer material in the photoresist unreserved region to form a first portion of the first via hole and a first portion of the second via hole; ashing the photoresist in the photoresist partially-reserved region, and etching the gate insulation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and removing the photoresist in the photoresist reserved region.

Optionally, the conductive part is a conductive connection line or a conductive connection strip.

In the embodiments of the present application, the following technical effects may be obtained.

In the above solutions, in the array substrate, the pixel electrode and the drain electrode are arranged on a same layer and not connected directly. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. a first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole. Thus, it prevents the defect of dislocation at the position of the overlapping slope caused by the pixel electrode directly overlapping the drain electrode. As a result, it enables to improve a connection between the pixel electrode and the drain electrode, ensure the display quality and improve the yield rate of the array substrate.

### BRIEF DESCRIPTION OF THE DRAWINGS

FIG. 1 is a sectional view of an array substrate; and

FIG. 2 is a sectional view of an array substrate according to an embodiment of the present disclosure.

### REFERENCE SIGNS

1 base substrate; 2 gate electrode; 3 gate insulation layer;

4 active layer; 5 source electrode; 6 drain electrode;

7 pixel electrode; 8passivation layer; 9 conductive part;

10 first via hole; 11 second via hole.

### DETAILED DESCRIPTION

Hereinafter, it will be discussed in details associated with figures and embodiments for further clarify technical problems, technical solutions and advantages of the embodiments of the present application.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

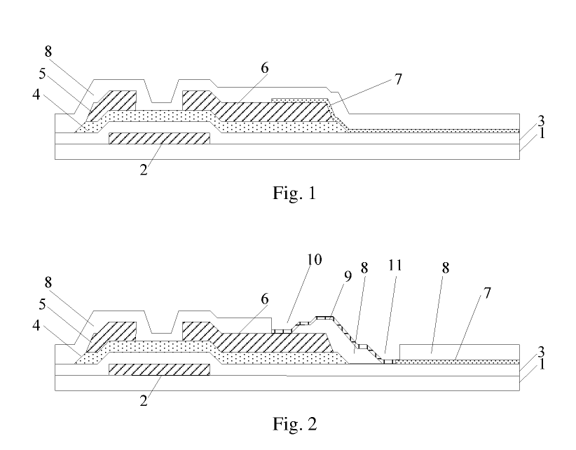

As illustrated in FIG. 1, a process for manufacturing a HADS array substrate includes: forming a gate electrode 2 and a gate line; forming an active layer 4; forming a source electrode 5, a drain electrode 6, a data line and a pixel electrode 7; and forming a common electrode. The pixel electrode 7 and the drain electrode 6 are arranged on a same layer, and the pixel 7 directly overlaps the drain electrode 6. Due to a thin thickness of pixel electrode 7, the defect of dislocation may easily occur at the position of the overlapping slope, such that the drain electrode 6 and the pixel electrode 7 are disconnected, and the drain electrode 6 is unable to supply a data signal to the pixel electrode 7, which may adversely affect a normal operation of the array substrate and reduce a yield rate of the array substrate.

In view of the above problem, the present disclosure provides an array substrate, a method for manufacturing the array substrate and a display device, so as to improve a connection between the pixel electrode and the drain electrode, and improve the yield rate of the array substrate.

The present disclosure provides in some embodiments an array substrate including a plurality of pixel regions. Each of the pixel regions includes: a pixel electrode and a drain electrode arranged on a same layer and independent from each other. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole.

The conductive part may be a conductive connection line, a conductive connection strip, or another conductive pattern with an irregular shape, as long as the pixel electrode and the drain electrode may be electrically connected.

In this embodiment, in the array substrate, the pixel electrode and the drain electrode are arranged on a same layer and not connected directly. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole. Thus, it prevents the defect of dislocation at the position of the overlapping slope caused by the pixel electrode directly overlapping the drain electrode. As a result, it enables to improve a connection between the pixel electrode and the drain electrode, ensure the display quality and improve the yield rate of the array substrate.

The insulation layer may be a passivation layer or a gate insulation layer.

In an embodiment, the pixel electrode, the drain electrode and the conductive part are separated from each other by a passivation layer. A first via hole penetrating through the passivation layer is formed in the passivation layer at a position corresponding to the drain electrode, and a second via hole penetrating through the passivation layer is formed in the passivation layer at a position corresponding to the pixel electrode. The drain electrode is connected to the conductive part through the first via hole, and the pixel electrode is connected to the conductive part through the second via hole.

Further, the conductive part and a common electrode are arranged on a same layer and made of a same material. Thus, the conductive part and the common electrode may be formed in a single patterning process, so as to form the conductive part without an additional patterning process.

Further, a step-like structure may be arranged in the first via hole, so as to prevent a relative large segment gap at a position where the conducive part and the drain electrode are connected, and thus improve the connection between the conductive part and the drain electrode. And a further step-like structure may be arranged in the second via hole, so as to prevent a relative large segment gap at a position where the conducive part and the drain electrode are connected, and thus improve the connection between the conductive part and the drain electrode.

In another embodiment, the pixel electrode, the drain electrode and the conductive part are separated from each other by a gate insulation layer. A first via hole penetrating through the gate insulation layer is formed in the gate insulation layer at a position corresponding to the drain electrode, and a second via hole penetrating through the gate insulation layer is formed in the gate insulation layer at a position corresponding to the pixel electrode. The drain electrode is connected to the conductive part through the first via hole, and the pixel electrode is connected to the conductive part through the second via hole.

Further, the conductive part and a gate electrode are arranged on a same layer and made of a same material. Thus, the conductive part and the gate electrode may by formed in a single patterning process, so as to form the conductive part without an additional patterning process.

Further, a step-like structure may be arranged in the first via hole, so as to prevent a relative large segment gap at a position where the conducive part and the drain electrode are connected, and thus improve the connection between the conductive part and the drain electrode. And a further step-like structure may be arranged in the second via hole, so as to prevent a relative large segment gap at a position where the conducive part and the drain electrode are connected, and thus improve the connection between the conductive part and the drain electrode.

In another aspect, the present disclosure provides a display device including the above array substrate. The display device may be a LCD panel, a LCD television, a LCD monitor, a digital photo frame, a mobile phone, a tablet computer, or any other product or part with the function of displaying.

In yet another aspect, the present disclosure provides a method for manufacturing an array substrate including a plurality of pixel regions. The method includes: forming a pixel electrode, a drain electrode and a conductive part in each of the pixel regions. The pixel electrode and the drain electrode are arranged on a same layer and independent from each other, and the pixel electrode and the drain electrode are connected by the conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole.

The conductive part may be a conductive connection line, a conductive connection strip, or another conductive pattern with an irregular shape, as long as the pixel electrode and the drain electrode may be electrically connected.

In this embodiment, the pixel electrode and the drain electrode are arranged on a same layer and not connected directly. The pixel electrode and the drain electrode are connected by a conductive part that is arranged on a different layer from the layer which the pixel electrode and the drain electrode are arranged on. The pixel electrode, the drain electrode and the conductive part are separated from each other by an insulation layer. A first via hole penetrating through the insulation layer is formed in the insulation layer at a position corresponding to the drain electrode, and a second via hole penetrating through the insulation layer is formed in the insulation layer at a position corresponding to the pixel electrode. The drain electrode is connected to the conductive part through the first via hole, and the pixel electrode is connected to the conductive part through the second via hole. Thus, it prevents the defect of dislocation at the position of the overlapping slope caused by the pixel electrode directly overlapping the drain electrode. As a result, it enables to improve a connection between the pixel electrode and the drain electrode, ensue the display quality and improve the yield rate of the array substrate.

In an embodiment, the insulation layer is a passivation layer, and forming the pixel electrode, the drain electrode and the conductive part includes: forming the pixel electrode and the drain electrode that are arranged on the same layer and independent from each other; forming the passivation layer covering the pixel electrode and the drain electrode, forming a first via hole in the passivation layer at a position corresponding to the drain electrode, and forming a second via hole in the passivation layer at a position corresponding to the pixel electrode, wherein each of the first via hole and the second via hole penetrates through the passivation layer; and forming a common electrode and the conductive part on the passivation layer through a single patterning process, wherein the drain electrode is connected to the conductive part through the first via hole, and the pixel electrode is connected to the conductive part through the second via hole.

Thus, the conductive part and the common electrode may by formed in a single patterning process, so as to form the conductive part without an additional patterning process.

Further, the forming the passivation layer includes: forming a layer of a passivation layer material; coating the layer of the passivation layer material with photoresist, exposing and developing the photoresist by a half-tone mask plate or a grey-tone mask plate, to form a photoresist reserved region, a photoresist partially-reserved region and a photoresist unreserved region; etching the passivation layer material in the photoresist unreserved region to form a first portion of the first via hole and a first portion of the second via hole; ashing the photoresist in the photoresist partially-reserved region, and etching the passivation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and removing the photoresist in the photoresist reserved region.

The step-like structure may be arranged in the first via hole, so as to prevent a relative large segment gap at a position where the conducive part and the drain electrode are connected, and thus improve the connection between the conductive part and the drain electrode. And the further step-like structure may be arranged in the second via hole, so as to prevent a relative large segment gap at a position where the conducive part and the drain electrode are connected, and thus improve the connection between the conductive part and the drain electrode.

In another embodiment, the insulation layer is a gate insulation layer, and the forming the pixel electrode, the drain electrode and the conductive part includes: forming a gate electrode and a conductive part through a single patterning process; forming the gate insulation layer covering the gate electrode and the conductive part, forming a first via hole in the gate insulation layer at a position corresponding to the drain electrode, and forming a second via hole in the gate insulation layer at a position corresponding to the pixel electrode, wherein each of the first via hole and the second via hole penetrates through the gate insulation layer; and forming the pixel electrode and the drain electrode on the gate insulation layer, wherein the pixel electrode and the drain electrode are independent from each other, the drain electrode is connected to the conductive part through the first via hole, and the pixel electrode is connected to the conductive part through the second via hole.

Thus, the conductive part and the gate electrode may by formed in a single patterning process, so as to form the conductive part without an additional patterning process.

Further, the forming the gate insulation layer includes: forming a layer of a gate insulation layer material; coating the layer of the gate insulation layer material with photoresist, exposing and developing the photoresist by a half-tone mask plate or a grey-tone mask plate, to form a photoresist reserved region, a photoresist partially-reserved region and a photoresist unreserved region; etching the gate insulation layer material in the photoresist unreserved region to form a first portion of the first via hole and a first portion of the second via hole; ashing the photoresist in the photoresist partially-reserved region, and etching the gate insulation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and removing the photoresist in the photoresist reserved region.

The step-like structure may be arranged in the first via hole, so as to prevent a relative large segment gap at a position where the conducive part and the drain electrode are connected, and thus improve the connection between the conductive part and the drain electrode. And the further step-like structure may be arranged in the second via hole, so as to prevent a relative large segment gap at a position where the conducive part and the drain electrode are connected, and thus improve the connection between the conductive part and the drain electrode.

In the following, as an example associating with FIG. 2, the conductive part and the common electrode are arranged on a same layer and made of a same material, and a method for manufacturing the array substrate may include following steps.

Step a: providing a base substrate 1; and forming a gate line and a gate electrode 2 of a TFT on the base substrate 1.

The base substrate 1 may be a glass substrate or a quartz substrate. In particular, a gate metal layer with a thickness of about 2500-16000 Å is deposited on the base substrate by a process of sputtering or thermal evaporation. The gate metal layer may be made of a metal such as Cu, Al, Ag, Mo, Cr, Nd, Ni, Mn, Ti, Ta, W or an alloy thereof. The gate metal layer may be of a single layer structure or a multi-layer structure, and the multi-layer structure may be of, for example Cu\Mo, Ti\Cu\Ti, Mo\Al\Mo or etc. Then, the gate metal layer is coated with photoresist. The photoresist is exposed by a mask plate to form a photoresist unreserved region and a photoresist reserved region, where the photoresist reserved region corresponds to a region where a pattern of the gate metal layer is located, and the photoresist unreserved region corresponds to a region other than the region where the pattern of the gate metal layer is located; a developing process is then performed to remove the photoresist in the photoresist unreserved region completely and remain the thickness of the photoresist in the photoresist reserved region. A film of the gate metal layer in the photoresist unreserved region is removed completely by an etching process, and the remaining photoresist is peeled off to form the pattern of the gate metal layer including the gate line and the gate electrode 2.

Step b: forming a gate insulation layer 3 on the substrate after the completion of step a.

In particular, the gate insulation layer 3 with the thickness of 500-5000 Å may be deposited on the substrate by a process of plasma enhanced chemical vapor deposition (PECVD) after the completion of step a. The gate insulation layer 3 may be made of the oxide, the nitride or the nitrogen oxide.

Step c: forming a pattern of an active layer 4 on the substrate after the completion of step b.

In particular, a semiconductor layer with the thickness of 500-5000 Å may be deposited on the substrate after the completion of step b, and the semiconductor layer is coated with a layer of photoresist. The photoresist is exposed by the mask plate to respectively form a photoresist unreserved region and a photoresist reserved region.

The photoresist reserved region corresponds to a region where a pattern of the semiconductor layer is located, and the photoresist unreserved region corresponds to a region other than the region where the pattern of the semiconductor layer is located. A developing process is performed to remove the photoresist in the photoresist unreserved region completely and remain the thickness of the photoresist in the photoresist reserved region. The film of the gate metal layer in the photoresist unreserved region is removed completely by an etching process, and the remaining photoresist is peeled off to form the pattern of the active layer 4.

Step d: forming a data line, a source electrode 5 and a drain electrode 6 of the TFT, and a pixel electrode 7 on the substrate after the completion of step c.

In particular, a source-drain metal layer with the thickness of about 2000-4000 Å may be formed on the substrate by a process of the magnetron sputtering, or the thermal evaporation, or another process for forming a film after the completion of step c. The source-drain metal layer may be made of metal such as Cu, Al, Ag, Mo, Cr, Nd, Ni, Mn, Ti, Ta or W, or the alloy of two or more of these metals. The source-drain metal layer may be in a single layer structure or a multi-layer structure, and the multi-layer structure may be of, for example Cu\Mo, Ti\Cu\Ti, Mo\Al\Mo or etc. A layer of photoresist is coated on the source-drain metal layer, the photoresist is exposed by the mask plate to respectively form the photoresist unreserved region and the photoresist reserved region. The photoresist reserved region corresponds to a region where the pattern of the source electrode 5, the drain electrode 6 and the data line are located, and the photoresist unreserved region corresponds to a region other than the region where the pattern of the source electrode 5, the drain electrode 6 and the data line are located. A developing process is performed to remove the photoresist in the photoresist unreserved region completely and remain the thickness of the photoresist in the photoresist reserved region. The source-drain metal layer in the photoresist unreserved region is removed completely by an etching process, and the remaining photoresist is peeled off to form the source electrode 5, the drain electrode 6 and the data line (not shown).

Then, a transparent conductive layer with the thickness of about 20-1000 Å may be formed on the substrate where the active electrode 5, the drain electrode 6 and the data line have been formed by a process of the magnetron sputtering, or the thermal evaporation, or another process for forming a film. The transparent conductive layer may be made of Indium Tin Oxide (ITO). The transparent conductive layer is coated with photoresist. The exposing process and developing process are performed. The transparent conductive layer is etched, and the photoresist is peeled off to form a pattern of the pixel electrode 7 consisting of the transparent conductive layer. As illustrated in FIG. 2, the pixel electrode 7 and the drain electrode 6 are arranged on a same layer, independent from each other and disconnected.

In the above steps, the pixel electrode 7 is made of a material different from that of the source electrode 5, the drain electrode 6 and the data line. Thus, the pixel electrode 7 and the source electrode 5, the drain electrode 6 and the data line are formed in two patterning processes respectively. In the case that the pixel electrode 7 is made of a material same as that of the source electrode 5, the drain electrode 6 and the data line, the pixel electrode 7, the source electrode 5, the drain electrode 6 and the data line may be formed by a single patterning process.

Step e: forming a pattern of a passivation layer 8 on the substrate after the completion of step d.

In particular, the passivation layer 8 with the thickness of about 400-5000 Å may be formed on the substrate by a process of the magnetron sputtering, the thermal evaporation, the PECVD, or another process for forming the film after the completion of step d. The passivation layer 8 may be made of the oxide, the nitride or the nitrogen oxide.

The passivation layer 8 is coated with photoresist, the photoresist is exposed and developed by a half-tone mask plate or a grey-tone mask plate to form a photoresist reserved region, a photoresist partially-reserved region and a photoresist unreserved region. The passivation layer material in the photoresist unreserved region is etched to form a first portion of the first via hole and a first portion of the second via hole. The photoresist in the photoresist partially-reserved region is ashed, the passivation layer material in the photoresist partially-reserved region is etched to form a second portion of the first via hole and a second portion of the second via hole. The first portion and second portion of the first via hole constitute the first via hole with a step-like structure, and the first portion and second portion of the second via hole constitute the second via hole with a step-like structure. The remaining photoresist is peeled off to form a pattern of the passivation layer 8 including the first via hole 10 and the second via hole 11. The first via hole 10 is arranged to correspond to the drain electrode 6, and the second via hole 11 is arranged to correspond to the pixel electrode 7.

Step f: forming a pattern of a conductive part 9 and a common electrode on the substrate after the completion of step e.

In particular, a transparent conductive layer with the thickness of about 20-1000 Å may be formed on the substrate by a process of the magnetron sputtering, or the thermal evaporation, or another process for forming a film after the completion of step e. The transparent conductive layer may be made of ITO. The transparent conductive layer is coated with photoresist. The exposing process and developing process are performed. The transparent conductive layer is etched, and the photoresist is peeled off to form a pattern of the conductive part 9 and the common electrode (not shown). The conductive part 9 is connected to the drain electrode 6 through the first via hole, and is connected to the pixel electrode 7 through the second via hole.

In this embodiment, the pixel electrode and the drain electrode are arranged on a same layer and not connected directly. The pixel electrode and the drain electrode are connected by a conductive part that is arranged on a different layer from the layer which the pixel electrode and the drain electrode are arranged on. Thus, it prevents the defect of dislocation at the position of the overlapping slope caused by the pixel electrode directly overlapping the drain electrode. As a result, it enables to improve a connection between the pixel electrode and the drain electrode, ensue the display quality and improve the yield rate of the array substrate. The conductive part and the common electrode may by formed in a single patterning process, so as to form the conductive part without an additional patterning process. In addition, a step-like structure may be arranged in the first via hole, so as to prevent a relative large segment gap at a position where the conducive part and the drain electrode are connected, and thus improve the connection between the conductive part and the drain electrode; and a further step-like structure may be arranged in the second via hole, so as to prevent a relative large segment gap at a position where the conducive part and the drain electrode are connected, and thus improve the connection between the conductive part and the drain electrode.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

1. An array substrate comprising a plurality of pixel regions, wherein each of the pixel regions comprises:
a pixel electrode and a drain electrode arranged on a same layer and independent from each other, wherein the pixel electrode and the drain electrode are connected by a conductive part that is arranged on a different layer from the layer which the pixel electrode and the drain electrode are arranged on,
wherein the pixel electrode, the drain electrode and the conductive part are separated from each other by an insulation layer, a first via hole penetrating through the insulation layer is formed in the insulation layer at a position corresponding to the drain electrode, a second via hole penetrating through the insulation layer is formed in the insulation layer at a position corresponding to the pixel electrode, the drain electrode is connected to the conductive part through the first via hole, and the pixel electrode is connected to the conductive part through the second via hole.

2. The array substrate according to claim 1, wherein the insulation layer is a passivation layer or a gate insulation layer.

3. The array substrate according to claim 2, wherein in the case that the insulation layer is the passivation layer, the conductive part and a common electrode are arranged on a same layer and made of a same material.

4. The array substrate according to claim 2, wherein in the case that the insulation layer is the gate insulation layer, the conductive part and a gate electrode are arranged on a same layer and made of a same material.

5. The array substrate according to claim 1, wherein a step-like structure is arranged in the first via hole and/or the second via hole.

6. The array substrate according to claim 1, wherein the conductive part is a conductive connection line or a conductive connection strip.

7. A display device comprising the array substrate according to claim 1.

8. A method for manufacturing an array substrate comprising a plurality of pixel regions, wherein the method comprises:
forming a pixel electrode, a drain electrode and a conductive part in each of the pixel regions, wherein the pixel electrode and the drain electrode are arranged on a same layer and independent from each other, and the pixel electrode and the drain electrode are connected by the conductive part that is arranged on a different layer from the layer which the pixel electrode and the drain electrode are arranged on,
wherein the pixel electrode, the drain electrode and the conductive part are separated from each other by an insulation layer, a first via hole penetrating through the insulation layer is formed in the insulation layer at a position corresponding to the drain electrode, a second via hole penetrating through the insulation layer is formed in the insulation layer at a position corresponding to the pixel electrode, the drain electrode is connected to the conductive part through the first via hole, and the pixel electrode is connected to the conductive part through the second via hole.

9. The method according to claim 8, wherein the insulation layer is a passivation layer, and forming the pixel electrode, the drain electrode and the conductive part comprises:
forming the pixel electrode and the drain electrode that are arranged on the same layer and independent from each other;
forming the passivation layer covering the pixel electrode and the drain electrode, forming a first via hole in the passivation layer at a position corresponding to the drain electrode, and forming a second via hole in the passivation layer at a position corresponding to the pixel electrode, wherein each of the first via hole and the second via hole penetrates through the passivation layer; and
forming a common electrode and the conductive part on the passivation layer through a single patterning process, wherein the drain electrode is connected to the conductive part through the first via hole, and the pixel electrode is connected to the conductive part through the second via hole.

10. The method according to claim 9, wherein forming the passivation layer comprises:
forming a layer of a passivation layer material;
coating the layer of the passivation layer material with photoresist, exposing and developing the photoresist by a half-tone mask plate or a grey-tone mask plate, to form a photoresist reserved region, a photoresist partially-reserved region and a photoresist unreserved region;
etching the passivation layer material in the photoresist unreserved region to form a first portion of the first via hole and a first portion of the second via hole;
ashing the photoresist in the photoresist partially-reserved region, and etching the passivation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and
removing the photoresist in the photoresist reserved region.

11. The method according to claim 8, wherein the insulation layer is a gate insulation layer, and forming the pixel electrode, the drain electrode and the conductive part comprises:
forming a gate electrode and a conductive part through a single patterning process;
forming the gate insulation layer covering the gate electrode and the conductive part, forming a first via hole in the gate insulation layer at a position corresponding to the drain electrode, and forming a second via hole in the gate insulation layer at a position corresponding to the pixel electrode, wherein each of the first via hole and the second via hole penetrates through the gate insulation layer; and
forming the pixel electrode and the drain electrode on the gate insulation layer, wherein the pixel electrode and the drain electrode are independent from each other, the drain electrode is connected to the conductive part through the first via hole, and the pixel electrode is connected to the conductive part through the second via hole.

12. The method according to claim 11, wherein forming the gate insulation layer comprises:
forming a layer of a gate insulation layer material;
coating the layer of the gate insulation layer material with photoresist, exposing and developing the photoresist by a half-tone mask plate or a grey-tone mask plate, to form a photoresist reserved region, a photoresist partially-reserved region and a photoresist unreserved region;
etching the gate insulation layer material in the photoresist unreserved region to form a first portion of the first via hole and a first portion of the second via hole;
ashing the photoresist in the photoresist partially-reserved region, and etching the gate insulation layer material in the photoresist partially-reserved region, to form a second portion of the first via hole and a second portion of the first via hole, wherein the first portion and second portion of the first via hole constitute the first via hole with a step-like structure, and the first portion and second portion of the second via hole constitute the second via hole with a step-like structure; and
removing the photoresist in the photoresist reserved region.

13. The method according to claim 8, wherein the conductive part is a conductive connection line or a conductive connection strip.

14. The display device according to claim 7, wherein the insulation layer is a passivation layer or a gate insulation layer.

15. The display device according to claim 14, wherein in the case that the insulation layer is the passivation layer, the conductive part and a common electrode are arranged on a same layer and made of a same material.

16. The display device according to claim 14, wherein in the case that the insulation layer is the gate insulation layer, the conductive part and a gate electrode are arranged on a same layer and made of a same material.

17. The display device according to claim 7, wherein a step-like structure is arranged in the first via hole and/or the second via hole.

18. The display device according to claim 7, wherein
the conductive part is a conductive connection line or a conductive connection strip.
